(19) United States
(12) Patent Application Publication
(10) Pub. No.: US 2022/0334195 A1
(43) Pub. Date: Oct. 20, 2022

(54) Method for Quantitative Diagnosis of Electricity Leakage or Micro-short-circuit in Single Cells Based on Capacity Estimation

(71) Applicant: UNIVERSITY OF SHANGHAI FOR SCIENCE AND TECHNOLOGY, SHANGHAI (CN)

(72) Inventors: Yuejiu ZHENG, SHANGHAI (CN); Anqi SHEN, SHANGHAI (CN); Xuebing HAN, SHANGHAI (CN); Minggao OUYANG, SHANGHAI (CN); Long ZHOU, SHANGHAI (CN)

(73) Assignee: UNIVERSITY OF SHANGHAI FOR SCIENCE AND TECHNOLOGY, SHANGHAI (CN)

(21) Appl. No.: 17/311,364

(22) PCT Filed: Jul. 22, 2020
(86) PCT No.: PCT/CN2020/103384

§ 371 Date: Jun. 7, 2021

(30) Foreign Application Priority Data
Jun. 23, 2020 (CN) 202010580826.5

(51) Int. Cl. G01R 31/52; G01R 31/388; G01R 31/396; G01R 31/36

(52) U.S. Cl. CPC G01R 31/52; G01R 31/388; G01R 31/396; G01R 31/3648

(57) ABSTRACT

The present invention discloses a method for quantitative diagnosis of electricity leakage or micro-short-circuit in single cells based on capacity estimation, comprising the steps as follows: S1 is obtaining the charge-discharge data of the cell; S2 is estimating the charge capacity C_{C} and discharge capacity C_{D} of the cell respectively by the traditional method of capacity estimation; S3 is calculating the ratio of discharge capacity to charge capacity and judging that leakage of electricity occurs when the ratio is less than the threshold; S4 is calculating the estimated value of leakage current according to the ratio of discharge capacity to charge capacity. According to the present invention, the quantitative diagnosis of leakage current of the single cell can be realized, which will improve the safety and reliability in use thereof.

### TECHNICAL FIELD

The present invention relates to the technical field of battery management systems, in particular to a method for quantitative diagnosis of electricity leakage or micro-short-circuit in single cells based on capacity estimation.

### BACKGROUND ART

Lithium ion batteries have the advantages of high specific energy density, high specific power, long cycle life, no memory effect, small self-discharge, easy use and the like. They are widely applied in consumer electronics, new energy vehicles, aviation, aerospace, ships and other fields. However, there are still some safety problems in lithium ion batteries, and fire and explosion accidents caused by lithium ion batteries are frequently reported. Particularly, thermal self-ignition, outbreak of fires and explosions of electric vehicle power batteries occurred in recent years, so that the safety of lithium ion batteries becomes the focus of attention. There are still short circuits due to manufacturing defects and other problems even in the mature field of consumer electronics, which eventually leads to self-ignition, explosion and other serious safety problems in mobile phones and other products.

Internal short-circuit of batteries is the most important factor causing thermal runaway of batteries in the process of normal use of batteries. The internal short-circuit of batteries is divided into three stages: initial stage, intermediate stage and final stage. The battery in the initial stage of internal short-circuit does not have obvious features, and it is difficult to identify the internal short-circuit. If the internal short-circuit is not timely detected and the use of battery is continued, the resistance of internal short-circuit will get smaller and smaller, which is very likely to cause thermal runaway of the battery, and then it will bring about a major dangerous accident. The time from the earlier stage of thermal runaway to complete thermal runaway is at the millisecond level, which means that there is no time for control management when thermal runaway occurs. As a result, the safety and reliability in use of power batteries can be greatly improved if internal short-circuit is timely detected and measures are taken in the initial stage. Meanwhile, the problem of leakage of electricity caused by an external circuit failing to pass a current sensor will additionally consume the battery energy, which has an adverse effect on the battery life. And the leakage current of the battery with micro-short-circuit cannot be measured in charge-discharge capacity estimation, so it cannot be considered. As a result, the estimated value of discharge capacity C_{D} is smaller than the actual capacity theoretically, while the estimated value of charge capacity C_{C} is greater than the actual capacity. Consequently, the leakage of electricity or the quantity of leakage of electricity in the battery with micro-short-circuit can be quantified by estimating the magnitudes of charge capacity C_{C} and discharge capacity C_{D} in the process of actual charge-discharge, and then the degree of leakage of electricity can be judged.

For the existing leakage or micro-short-circuit fault diagnosis algorithm, qualitative or quantitative micro-short-circuit detection is typically performed using statistical characteristics through horizontal comparison by the method of using healthy battery cells in a serial battery pack as references. These methods have good effects on the identification of leakage or micro-short-circuit with healthy battery cells as references when there are a large number of serial battery cells. For application scenarios with a single battery cell, however, the existing methods cannot diagnose leakage or micro-short-circuit for lack of a healthy battery cell as a reference.

### SUMMARY OF THE INVENTION

In view of the deficiencies existing in the prior art, the present invention aims to provide a method for quantitative diagnosis of electricity leakage or micro-short-circuit in single cells based on capacity estimation, which can realize quantitative diagnosis of leakage current in a single cell, and then improve the safety and reliability in use thereof. To achieve the above purposes and other advantages according to the present invention, a method for quantitative diagnosis of electricity leakage or micro-short-circuit in single cells based on capacity estimation is provided, comprising the following steps:

S1. Obtaining the charge-discharge data of the cell;

S2. Estimating the cell capacity C_{C} and discharge capacity C_{D} respectively by the traditional method of capacity estimation;

S3. Calculating the ratio of discharge capacity to charge capacity, and judging whether leakage of electricity occurs to the cell by comparing the ratio with the threshold;

S4. Calculating the estimated value of leakage current according to the ratio of discharge capacity to charge capacity.

Preferably, the steps as follows are also included in the Step S2:

S21. Building a first-order RC equivalent circuit model of the cell for online identification of the parameter OCV of the cell by forgetting factor recursive least squares;

S22. Obtaining SOC by table look-up according to the relationship of OCV-SOC;

S23. Estimating the capacities C_{D} and C_{C} of the cell respectively online according to the energy accumulation approach between two points.

Preferably, in the Step S23, two different moments with greater ΔSOC and smaller Δt shall be selected for calculation, i.e. a high SOC point and a low SOC point are selected for capacity estimation during charge-discharge capacity estimation by applying the energy accumulation approach between two points.

Preferably, in the Step S3, the ratio of discharge capacity C_{D} to charge capacity C_{C} is κ, when κ is less than the threshold κ₀, it is judged that leakage of electricity occurs to the cell, when κ is greater than or equal to the threshold κ₀, the cell is considered as normal.

Preferably, the κ₀ is the diagnosis threshold, the κ₀ is determined by the error e_{c} existing in capacity estimation, and the formula is κ₀=1−e_{c}.

Preferably, the Step S4 further includes the following steps:

S41. Setting the average charge-discharge currents Ī_{C} and Ī_{D} according to the charge-discharge habits of cell application, wherein the charge current is negative and the discharge current is positive as specified;

S42. Determining the theoretical estimated capacities C_{D} and C_{C} of the cell according to the set leakage current;

S43. Evaluating the ratio κ_{T}; of discharge capacity C_{D} to charge capacity C_{C} theoretically estimated at the set leakage current;

S44. Let κ=κ_{T}, then the leakage current can be estimated as

$${I}_{L} = \frac{( 1 - κ ) {\overline{I}}_{D} {\overline{I}}_{C}}{k {\overline{I}}_{C} - {\overline{I}}_{D}}$$

Preferably, in the Step S42, the theoretical relationship between charge capacity and actual capacity C₀ is

$${C}_{C} = \frac{{\overline{I}}_{C}}{{\overline{I}}_{C} + {I}_{L}} {C}_{0} > {C}_{0} ,$$

and the theoretical relationship between discharge capacity and actual capacity is

$${C}_{D} = \frac{{\overline{I}}_{D}}{{\overline{I}}_{D} + {I}_{L}} {C}_{0} < {C}_{0} .$$

Compared with the prior art, the present invention has the beneficial effects that: through the diagnostic method in the present invention, the current state of the cell can be determined to judge whether the cell has leakage of electricity or micro-short-circuit fault, or the cell is in a normal state, and the degree of leakage in the cell can be quantitatively diagnosed. In the present invention, the cell capacities are estimated respectively according to the charge-discharge data of the cell, and then the leakage quantity of the cell can be quantitatively diagnosed according to the estimated cell capacity size. Compared with the existing methods generally depending on healthy cells within a serial battery pack as references, this diagnosis method allows quantitative diagnosis of leakage of electricity or micro-short-circuit for these application scenarios with a large number of single battery cells, such as mobile phones and other consumer electronics.

### DESCRIPTION OF DRAWINGS

FIG. 1 is a flow chart of the method for quantitative diagnosis of electricity leakage or micro-short-circuit in single cells based on capacity estimation according to the present invention;

FIG. 2 is a theoretical relationship diagram of estimated value of single cell capacity in the method for quantitative diagnosis of electricity leakage or micro-short-circuit in single cells based on capacity estimation according to the present invention;

FIG. 3 is a diagram of SOC estimation result curves according to the method for quantitative diagnosis of electricity leakage or micro-short-circuit in single cells based on capacity estimation of the present invention.

### DETAILED DESCRIPTION OF THE PREFERRED EMBODIMENT

A clear and complete description of the technical solution in the embodiments of the present invention will be provided below in combination with the drawings in the embodiments of the present invention. Obviously, the described embodiments are not all the embodiments of the present invention but only part of them. Based on the embodiments in the present invention, all other embodiments obtained by one of ordinary skill in the art without creative labor should be deemed falling within the protection scope of the present invention.

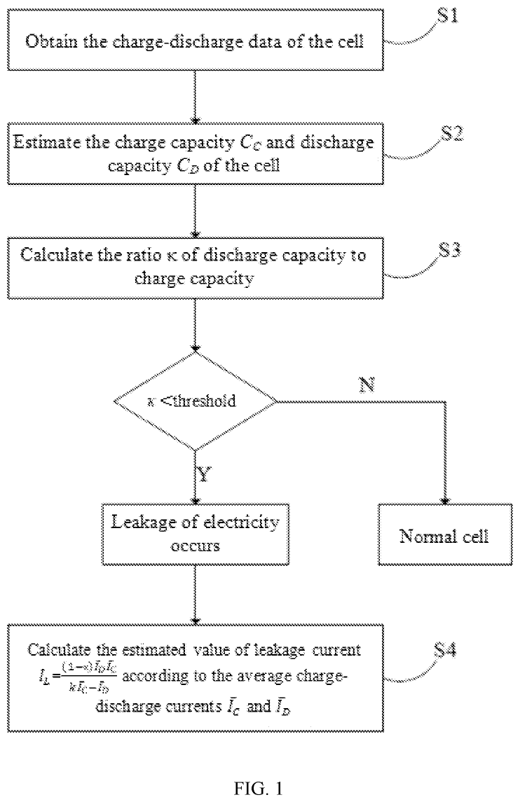

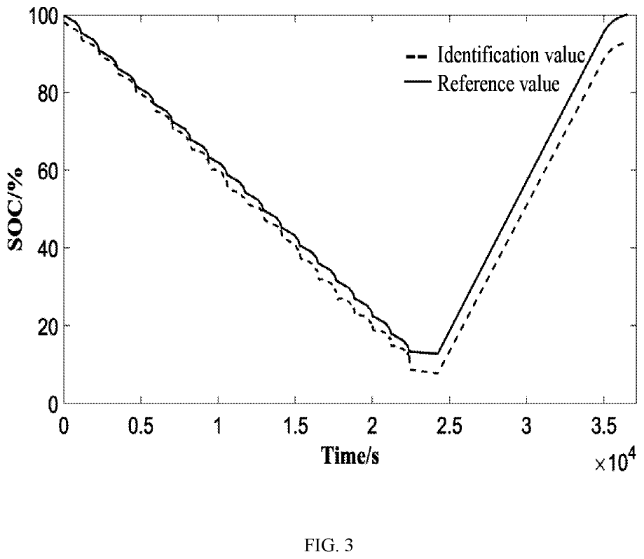

Refer to FIGS. 1-3, a method for quantitative diagnosis of electricity leakage or micro-short-circuit in single cells based on capacity estimation, comprising the following steps:

S1. Obtaining the charge-discharge data of the cell, wherein the charge-discharge data of the cell comprises voltage and current during at least one charge-discharge process of the cell, and the charge-discharge depth is above 70%;

S2. Estimating the cell capacity C_{C} and discharge capacity C_{D} respectively by the traditional method of capacity estimation;

S3. Calculating the ratio of discharge capacity to charge capacity, and judging whether leakage of electricity occurs to the cell by comparing the ratio with the threshold;

S4. Calculating the estimated value of leakage current according to the ratio of discharge capacity to charge capacity.

In the Step S2, there are various forms of charge-discharge capacity estimation, and the methods include, but are not limited to, the following two major categories. The first category is measuring the features of the cell and combining the calibration model of capacity and feature based on a certain feature of the cell to obtain the estimation results of cell capacity. Common features include differential voltage, charge-discharge curves, incremental capacity curves, etc. of the cell. The second category is that the State Of Charge (SOC) of cell, a value between 0% and 100%, reflects the remaining electricity quantity of the cell based on the variation in charge-discharge electricity quantity/corresponding variation in SOC, and the value is an important internal state in BMS. As shown in the following formula, SOC and cell capacity can be linked by equation:

$${C}_{n o r m} = \frac{Δ Q}{Δ SOC} = \frac{{\int }_{{t}_{1}}^{{t}_{2}} \frac{η I ( t )}{3600} dt}{S OC ( {t}_{2} ) - S OC ( {t}_{1} )}$$

Where, Cₙₒᵣₘ is the total capacity of cell, ΔQis the variation in electricity quantity, ΔSOC is the variation in SOC, SOC(t₁) is the state of charge of cell at moment t₁, SOC(t₂) is the state of charge of cell at moment t₂, I(t) is the cell current at moment t, η is the coulombic efficiency (generally η≈1), and 3600 is the factor that converts seconds into hours.

Further, the steps as follows are also included in the Step S2:

S21. Building a first-order RC equivalent circuit model of the cell for online identification of the parameter OCV of the cell by forgetting factor recursive least squares, wherein the built first-order RC equivalent circuit model has simple structure, easy parameter identification and relatively low calculated quantities. For online identification of the model parameter OCV of the cell by forgetting factor recursive least squares (FFRLS), different weighting coefficients are given to the data at different moments by introducing the forgetting factor, real-time data is added while historical data is reduced, the effect of new data on the current identification results is enhanced, thus achieving the reliable identification of system parameters;

S22. Obtaining SOC by table look-up according to the relationship of OCV-SOC;

S23. Estimating the capacities C_{C} and C_{D} of the cell respectively online according to the energy accumulation approach between two points.

Further, in the Step S23, two different moments with greater ΔSOC and smaller Δt shall be selected for calculation, i.e. a high SOC point and a low SOC point are selected for capacity estimation during charge-discharge capacity estimation by applying the energy accumulation approach between two points.

Further, in the Step S3, the ratio of discharge capacity C_{D} to charge capacity C_{C} is κ, when κ is less than the threshold κ₀, it is judged that leakage of electricity occurs to the cell, when κ is greater than or equal to the threshold κ₀, the cell is considered as normal.

Further, the κ₀ is the diagnosis threshold, the κ₀ is determined by the error e_{c} existing in capacity estimation, and the formula is κ₀=1−e_{c}.

Further, the Step S4 further includes the following steps:

S41. Setting the average charge-discharge currents Ī_{C} and Ī_{D} according to the charge-discharge habits of cell application, wherein the charge current is negative and the discharge current is positive as specified;

S42. Determining the theoretical estimated capacities C_{D} and C_{C} of the cell according to the set leakage current;

S43. Evaluating the ratio κ_{T} of discharge capacity C_{D} to charge capacity C_{C} theoretically estimated at the set leakage current, and it is known from Step S42 with I_{L}<|Ī_{C}| and I_{L}<Ī_{D} that

$${κ}_{T} = \frac{{C}_{D}}{{C}_{C}} = \frac{{\overline{I}}_{D} ( {\overline{I}}_{C} + {I}_{L} )}{{\overline{I}}_{C} ( {\overline{I}}_{D} + {I}_{L} )} = \frac{1 + \frac{{I}_{L}}{{\overline{I}}_{C}}}{1 + \frac{{I}_{L}}{{\overline{I}}_{D}}} \approx 1 + \frac{{I}_{L}}{{\overline{I}}_{C}} - \frac{{I}_{L}}{{\overline{I}}_{D}} < 1$$

S44. Let κ=κ_{T}, then the leakage current can be estimated as

$${I}_{L} = \frac{( 1 - κ ) {\overline{I}}_{D} {\overline{I}}_{C}}{k {\overline{I}}_{C} - {\overline{I}}_{D}} .$$

Further, in the Step S42, the theoretical relationship between charge capacity and actual capacity C₀ is

$${C}_{C} = \frac{{\overline{I}}_{C}}{{\overline{I}}_{C} + {I}_{L}} {C}_{0} > {C}_{0} ,$$

and the theoretical relationship between discharge capacity and actual capacity is

$${C}_{D} = \frac{{\overline{I}}_{D}}{{\overline{I}}_{D} + {I}_{L}} {C}_{0} < {C}_{0} .$$

As shown in FIG. 1, an embodiment, specifically, the charge-discharge data of the cell comprises the voltage and current during at least one charge-discharge process of the cell, and the charge-discharge depth is above 70%. In this embodiment, a ternary lithium cell with capacity of 3.0442 Ah is selected for diagnosis, the cell is connected with 100Ω resistance to simulate its short circuit to obtain the current and voltage data thereof in a charge-discharge process.

Step S2 is estimating the charge capacity C_{C} and discharge capacity C_{D} of the cell respectively by the traditional method of capacity estimation.

In this embodiment, the charge-discharge capacity is estimated by the method based on variation in charge-discharge electricity quantity/corresponding variation in SOC, and the specific steps are as follows:

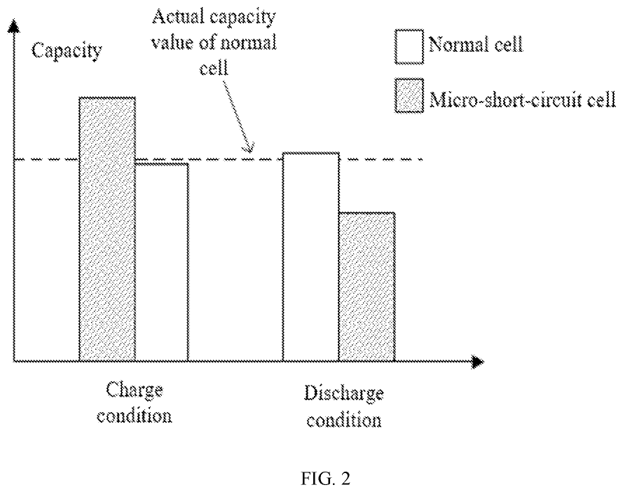

Step S21 is building a first-order RC equivalent circuit model of the cell as shown in FIG. 2 for online identification of the parameter OCV of the cell by forgetting factor recursive least squares;

The output equation of the system is: Uₖ=θ₁Uₖ₋₁+θ₂Iₖ+θ₃Iₖ₋₁+θ₄ where,

$${θ}_{1} = \frac{2 τ - 1}{2 τ + 1} , {θ}_{2} = \frac{{R}_{S} + 2 {R}_{0} τ + {R}_{0}}{2 τ + 1} , \\ {θ}_{3} = \frac{{R}_{S} - 2 {R}_{0} τ + {R}_{0}}{2 τ + 1} , {θ}_{4} = ( 1 - {θ}_{1} ) {OCV}_{k - 1}$$

The recurrence formula of forgetting factor recursive least squares is as follows:

$${K}_{k} = \frac{{P}_{k - 1} {φ}_{k}}{λ + {φ}_{k}^{T} {P}_{k - 1} {φ}_{k}} \\ {θ}_{k} = {θ}_{k - 1} + {K}_{k} ( {y}_{k} - {φ}_{k}^{T} {θ}_{k - 1} ) \\ {P}_{k} = \frac{1}{λ} ( {P}_{k - 1} - {K}_{k} {φ}_{k}^{T} {P}_{k - 1} )$$

where, φₖ is a measurement vector consisting of observed value, and θₖ is a vector to be estimated including the parameter to be estimated. Pₖ is the covariance matrix, Kₖ is the gain, and λ is the forgetting factor, with a value ranging between 0 and 1.

Defining yₖ=Uₖ as system output, θ=[θ₁, θ₂, θ₃, θ₄]^{T} as the parameter vector to be identified, φk₌[Uₖ₋₁, Iₖ, Iₖ₋₁, I]^{T} as the data vector, the parameter θ to be identified can be obtained by applying the above recurrence formula, and then

$$OCV = \frac{{θ}_{4}}{1 - {θ}_{1}}$$

can be obtained.

StepS22 is obtaining SOC by table look-up according to the relationship of OCV-SOC, the estimation results of which are shown in FIG. 4, and the diagram of OCV-SOC calibration curves is obtained from the HPPC experiment.

Step S23 is estimating the capacities C_{D} and C_{c} of the cell respectively online according to the energy accumulation approach between two points, and the formula is as follows:

$${C}_{n o r m} = \frac{Δ Q}{Δ SOC} = \frac{{\int }_{{t}_{1}}^{{t}_{2}} \frac{η I ( t )}{3600} dt}{S OC ( {t}_{2} ) - S OC ( {t}_{1} )}$$

Where, Cₙₒᵣₘ is the total capacity of cell, ΔQis the variation in electricity quantity, ΔSOC is the variation in SOC, SOC(t₁) is the state of charge of cell at momentt₁, SOC(t₂) is the state of charge of cell at moment t₂, I(t) is the cell current at moment t, η is the coulombic efficiency (generally η≈1), and 3600 is the factor that converts seconds into hours. The two points, SOC=20% and SOC=90%, are selected for capacity estimation in this embodiment to obtain the results of C_{D}=2.7726 Ah, and C_{C}=3.1820 Ah.

Step S3 is calculating the ratio κ of discharge capacity to charge capacity and judging that leakage of electricity occurs when κ is less than the threshold κ₀, when κ is greater than or equal to the threshold κ₀, the cell is considered as normal. Especially, the method for determining threshold κ₀ is that κ₀=1−e_{c} with the error e_{c} existing in capacity estimation. When implemented, the capacity estimation error e_{c} shall be less than or equal to 5% of the rated capacity of the cell.

Step S4 is giving the estimated value of leakage current according to the ratio of discharge capacity to charge capacity.

Then giving the estimated value of leakage current according to the ratio κ of discharge capacity C_{D} to charge capacity C_{C}, and the method is as follows:

Step S41 is setting the average charge-discharge currents according to the charge-discharge habits of cell application;

Setting the average charge-discharge currents Ī_{C} and Ī_{D} of the cell according to the average charge-discharge time of the cell, wherein the charge current is negative and the discharge current is positive as specified. From the charge-discharge current and corresponding charge-discharge time data obtained in the above embodiment, the average charge-discharge current thereof can be calculated as Ī_{D}=0.3951A, Ī_{C}=−0.6246A.

Step S42 is determining the theoretical estimated capacities C_{D} and C_{C} of the cell according to the set leakage current, assuming the leakage current as I_{L}, which is specified as positive, the actual capacity of the cell is C₀, then the theoretical relationship between charge capacity and actual capacity is

$${C}_{C} = \frac{{\overline{I}}_{C}}{{\overline{I}}_{C} + {I}_{L}} {C}_{0} > {C}_{0} ,$$

and the theoretical relationship between discharge capacity and actual capacity is

$${C}_{D} = \frac{{\overline{I}}_{D}}{{\overline{I}}_{D} + {I}_{L}} {C}_{0} < {C}_{0} .$$

Step S43 is eva|l̅|uating the ratio κ_{T} of discharge capacity C_{D} to charge capacity C_{C} theoretically estimated at the set leakage current, and it is known from S42 with I_{L}<|Ī_{C}| and I_{L}<Ī_{D} that

$${κ}_{T} = \frac{{C}_{D}}{{C}_{C}} = \frac{{\overline{I}}_{D} ( {\overline{I}}_{C} + {I}_{L} )}{{\overline{I}}_{C} ( {\overline{I}}_{D} + {I}_{L} )} = \frac{1 + \frac{{I}_{L}}{{\overline{I}}_{C}}}{1 + \frac{{I}_{L}}{{\overline{I}}_{D}}} \approx 1 + \frac{{I}_{L}}{{\overline{I}}_{C}} - \frac{{I}_{L}}{{\overline{I}}_{D}} < 1$$

Step S44 Let κ=κ_{T}, then the leakage current can be estimated as

$${I}_{L} = \frac{( 1 - κ ) {\overline{I}}_{D} {\overline{I}}_{C}}{k {\overline{I}}_{C} - {\overline{I}}_{D}} .$$

According to the evaluated capacity error in the above embodiment, the threshold thereof is determined as κ₀=1−0.03=0.97, the ratio of charge capacity to discharge capacity

$$κ = \frac{{C}_{D}}{{C}_{C}} = \frac{2.7726}{3.182} \approx 0.8 \; 713 < {κ}_{0} ,$$

which can be obviously judged as occurrence of leakage of electricity. By substituting the results obtained in the embodiment into Step S44, it can be estimated that the average leakage current is I_{L}=33.8 mA, while the actual average leakage current is 38 mA, with estimated error within 10 mA. Therefore, it can be seen that a method for quantitative diagnosis of electricity leakage or micro-short-circuit in single cells based on capacity estimation as adopted in the present invention allows rapid diagnosis of whether leakage of electricity occurs to the cell or micro-short-circuit fault diagnosis as well as quantitative judgment of the degree of leakage of electricity thereof.

The quantity of devices and processing scale described herein are used to simplify the description of the present invention, and the application, modification and change of the present invention are obvious for those skilled in the art.

Although the embodiment of the present invention has been disclosed as above, it is not limited to the applications set forth in the description and embodiments. It can be absolutely made available for various fields suitable for the present invention. For those familiar with the field, additional modifications can be easily implemented. Therefore, the present invention is not limited to specific details and the illustrations shown and described herein without departing from the general concepts defined by the claims and the equivalent scope.

1. A method for quantitative diagnosis of electricity leakage or micro-short-circuit in single cells based on capacity estimation, characterized in that it comprises the following steps:
S1. Obtaining the charge-discharge data of the cell;
S2. Estimating the charge capacity C_{C} and discharge capacity C_{D} of the cell respectively by the traditional method of capacity estimation;
S3. Calculating the ratio of discharge capacity to charge capacity, and judging whether leakage of electricity occurs to the cell by comparing the ratio with the threshold;
S4. Calculating the estimated value of leakage current according to the ratio of discharge capacity to charge capacity.

2. The method for quantitative diagnosis of electricity leakage or micro-short-circuit in single cells based on capacity estimation according to claim 1, characterized in that the steps as follows are also included in the Step S2:
S21. Building a first-order RC equivalent circuit model of the cell for online identification of the parameter OCV of the cell by forgetting factor recursive least squares;
S22. Obtaining SOC by table look-up according to the relationship of OCV-SOC;
S23. Estimating the capacities C_{D} and C_{C} of the cell respectively online according to the energy accumulation approach between two points.

3. The method for quantitative diagnosis of electricity leakage or micro-short-circuit in single cells based on capacity estimation according to claim 2, characterized in that in the Step S23, two different moments with greater ΔSOC and smaller Δt shall be selected for calculation, i.e. a high SOC point and a low SOC point are selected for capacity estimation during charge-discharge capacity estimation by applying the energy accumulation approach between two points.

4. The method for quantitative diagnosis of electricity leakage or micro-short-circuit in single cells based on capacity estimation according to claim 1, characterized in that in the Step S3, the ratio of discharge capacity C_{D} to charge capacity C_{C} is κ, when κ is less than the threshold κ₀, it is judged that leakage of electricity occurs to the cell, when κ is greater than or equal to the threshold κ₀, the cell is considered as normal.

5. The method for quantitative diagnosis of electricity leakage or micro-short-circuit in single cells based on capacity estimation according to claim 4, characterized in that the κ₀ is the diagnosis threshold, the κ₀ is determined through the error e_{c} existing in capacity estimation, and the formula is κ₀=1−e_{c}.

6. The method for quantitative diagnosis of electricity leakage or micro-short-circuit in single cells based on capacity estimation according to claim 1, characterized in that the Step S4 further includes the following steps:
S41. Setting the average charge-discharge currents Ī_{C} and Ī_{D} according to the charge-discharge habits of cell application, wherein the charge current is negative and the discharge current is positive as specified;
S42. Determining the theoretical estimated capacities C_{D} and C_{C} of the cell according to the set leakage current;
S43. Evaluating the ratio κ_{T} of discharge capacity C_{D} to charge capacity C_{C} theoretically estimated at the set leakage current, S44. Let κ=κ_{T}, then the leakage current can be estimated as
$${I}_{L} = \frac{( 1 - κ ) {\overline{I}}_{D} {\overline{I}}_{C}}{k {\overline{I}}_{C} - {\overline{I}}_{D}}$$

7. The method for quantitative diagnosis of electricity leakage or micro-short-circuit in single cells based on capacity estimation according to claim 6, characterized in that in the Step S42, the theoretical relationship between charge capacity and actual capacity C₀ is
$${C}_{C} = \frac{{\overline{I}}_{C}}{{\overline{I}}_{C} + {I}_{L}} {C}_{0} < {C}_{0} ,$$
and the theoretical relationship between discharge capacity and actual capacity is
$${C}_{D} = \frac{{\overline{I}}_{D}}{{\overline{I}}_{D} + {I}_{L}} {C}_{0} < {C}_{0} .$$
